(19) United States
(12) Patent Application Publication
(10) Pub. No.: US 2025/0384922 A1
(43) Pub. Date: Dec. 18, 2025

(54) EVALUATION CIRCUIT FOR STATIC RANDOM-ACCESS MEMORY OPERATIONS

(71) Applicant: Faraday Technology Corp., Hsinchu (TW)

(72) Inventors: Wei-Hao Chen, Hsinchu (TW); Chi-Chang Shuai, Hsinchu (TW)

(73) Assignee: Faraday Technology Corp., Hsinchu (TW)

(21) Appl. No.: 18/889,380

(22) Filed: Sep. 19, 2024

(30) Foreign Application Priority Data
Jun. 12, 2024 (TW) 113121601

(51) Int. Cl. G11C 11/419; G11C 11/418

(52) U.S. Cl. CPC G11C 11/419; G11C 11/418

(57) ABSTRACT

The disclosure provides an evaluation circuit for SRAM operations. The evaluation circuit includes a ring-oscillation control circuit and a plurality of SRAM instances connected in series with each other into an SRAM string. A WLE signal input terminal of an intermediate SRAM instance in the SRAM string is coupled to an internal signal output terminal of a previous-stage SRAM instance, and an internal signal output terminal of the intermediate SRAM instance is coupled to a WLE signal input terminal of a next-stage SRAM instance. An input terminal of the ring-oscillation control circuit is coupled to an internal signal output terminal of a last-stage SRAM instance in the SRAM string, and an output terminal of the ring-oscillation control circuit is coupled to a WLE signal input terminal of a first-stage SRAM instance in the SRAM string. Therefore, the ring-oscillation control circuit and the SRAM string form a ring oscillator circuit.

### CROSS-REFERENCE TO RELATED APPLICATION

This application claims the priority benefit of Taiwan application serial no. 113121601, filed on Jun. 12, 2024. The entirety of the above-mentioned patent application is hereby incorporated by reference herein and made a part of this specification.

### BACKGROUND

### Technical Field

The disclosure relates to an evaluation technology for an integrated circuit process, and particularly relates to an evaluation circuit for static random-access memory (SRAM) operations.

### Description of Related Art

Modeling and simulation are common auxiliary tools used to evaluate the SRAM operating performance. However, due to various factors such as process variations, SRAM simulation results are often unable to accurately predict the SRAM operating performance. Measuring the characteristics of the SRAM cell directly from hardware, such as measuring the actual current of the SRAM cell, is an intuitive method to evaluate the SRAM operating performance. However, other operating performance and related process information of SRAM instances cannot be known by only measuring the characteristics of the SRAM cell.

It should be noted that the content of the “BACKGROUND” section is used to help understand the disclosure. Some of the content (or all of the content) disclosed in the “BACKGROUND” section may not be known to those of ordinary skill in the art. The content disclosed in the “BACKGROUND” section does not mean that the content has been known to those of ordinary skill in the art before the application of the disclosure.

### SUMMARY

The disclosure provides an evaluation circuit for SRAM operations that uses a memory internal signal to track process information.

In an embodiment of the disclosure, the evaluation circuit includes a plurality of SRAM instances and a ring-oscillation control circuit. The SRAM instances are connected in series with each other into an SRAM string. A word line enable (WLE) signal input terminal of an intermediate SRAM instance in the SRAM string is coupled to an internal signal output terminal of a previous-stage SRAM instance of the intermediate SRAM instance, and an internal signal output terminal of the intermediate SRAM instance is coupled to a WLE signal input terminal of a next-stage SRAM instance of the intermediate SRAM instance. The ring-oscillation control circuit is coupled to the SRAM string to form a ring oscillator circuit. An input terminal of the ring-oscillation control circuit is coupled to an internal signal output terminal of a last-stage SRAM instance in the SRAM string, and an output terminal of the ring-oscillation control circuit is coupled to a WLE signal input terminal of a first-stage SRAM instance in the SRAM string.

Based on the above, the embodiment of the disclosure uses the plurality of SRAM instances to form an SRAM ring oscillator. Any SRAM instance (complete SRAM integrated circuit) in the SRAM ring oscillator generates different internal control signals (used to control different functional circuits local to the SRAM instances) based on the WLE signal received by its own WLE signal input terminal. At least one of the internal control signals is transmitted to the internal signal output terminal as a WLE signal for another SRAM instance. By comparing the actual oscillation signal of the SRAM ring oscillator (the internal control signal output by any one-stage SRAM instance) to the simulation waveform, the analysis platform can extract instance level AC information, instance level DC information, or other information, and track the process information of memory cell current, the process information of memory metal RC loading model, or the process information of memory internal signal. The above evaluation circuit can be placed on a wafer process monitoring structure for product SRAM instance monitoring.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 is a schematic circuit block diagram of an evaluation circuit for SRAM operations according to an embodiment of the disclosure.

FIG. 2 is a schematic circuit block diagram of an SRAM instance according to an embodiment of the disclosure.

FIG. 3 is a schematic circuit block diagram of an SRAM instance according to an embodiment of the disclosure.

### DESCRIPTION OF THE EMBODIMENTS

The word “coupled to (or connected to)” as used throughout this specification (including the scope of the application) may refer to any direct or indirect means of connection. For example, if it is described in the specification that a first device is coupled (or connected) to a second device, it should be construed that the first device may be directly connected to the second device, or the first device may be indirectly connected to the second device through another device or some type of connecting means. The terms “first” and “second” and the like mentioned in the full text (including the scope of the patent application) of the description of this application are used only to name the elements or to distinguish different embodiments or scopes and are not intended to limit the upper or lower limit of the number of the elements, nor is it intended to limit the order of elements. Also, where possible, elements/components/steps using the same reference numerals in drawings and embodiments represent the same or similar parts. Elements/components/steps that use the same reference numerals or use the same terminology in different embodiments may refer to relative descriptions of each other.

The cell based ring oscillator can only track the process information of memory cell current. Different from the “cell based ring oscillator”, the following embodiments will illustrate the “instance based memory ring oscillator” as an evaluation circuit for SRAM operations. In addition to tracking the process information of memory cell current, the instance based memory ring oscillator can also track the process information of memory metal RC loading model and the process information of memory internal signal. The instance based memory ring oscillator can extract the instance level AC information and also extract the instance level DC information.

FIG. 1 is a schematic circuit block diagram of an evaluation circuit 100 for SRAM operations according to an embodiment of the disclosure. The evaluation circuit 100 can be placed on a wafer process monitoring structure to implement product SRAM instance monitoring. The evaluation circuit 100 includes a ring-oscillation control circuit 110 and a plurality of SRAM instances, such as SRAM instances 120_1, 120_2, . . . , 120_N shown in FIG. 1. The SRAM instances 120_1 to 120_N are connected in series with each other into an SRAM string. The number N of SRAM instances 120_1 to 120_N may be any odd number determined according to the actual design.

In the SRAM string, a WLE signal input terminal of any intermediate SRAM instance (such as the SRAM instance 120_2) is coupled to an internal signal output terminal of a previous-stage SRAM instance (such as the SRAM instance 120_1) to receive an internal control signal of the previous-stage SRAM instance (such as an internal control signal WLE1_1 of the SRAM instance 120_1). An internal signal output terminal of the intermediate SRAM instance (such as the SRAM instance 120_2) is coupled to a WLE signal input terminal of a next-stage SRAM instance (such as the SRAM instance 120_3, not shown) to provide its own internal control signal (such as an internal control signal WLE1_2 of the SRAM instance 120_2). Similarly, it can be deduced that a WLE signal input terminal of the SRAM instance 120_N is coupled to the internal signal output terminal of the previous-stage SRAM instance (such as the SRAM instance 120_N−1, not shown) to receive the internal control signal of the previous-stage SRAM instance (such as an internal control signal WLE1_N−1).

The internal signal output terminal of any one of the SRAM instances 120_1 to 120_N is used to output a local internal control signal. In different practical application scenarios, the internal control signal output by the internal signal output terminal includes a dummy bit line signal, a bit line precharge (BL precharge) signal, a sense amplifier enable (SAEN) signal, a word line (WL) signal, a multiplexer select signal, or other internal control signals.

The ring-oscillation control circuit 110 is coupled to the SRAM string to form a ring oscillator circuit. Specifically, an input terminal of the ring-oscillation control circuit 110 is coupled to an internal signal output terminal of a last-stage SRAM instance 120_N in the SRAM string to receive an internal control signal WLE1_N of the SRAM instance 120_N. An output terminal of the ring-oscillation control circuit 110 is coupled to a WLE signal input terminal of a first-stage SRAM instance 120_1 in the SRAM string to selectively provide the internal control signal WLE1_N of the SRAM instance 120_N to the SRAM instance 120_1 as a WLE signal WLE1_0. The ring-oscillation control circuit 110 is controlled by an evaluation enable signal EN.

When the evaluation enable signal EN indicates that the evaluation is terminated, the ring-oscillation control circuit 110 disconnects the connection between the input terminal of the ring-oscillation control circuit 110 and the output terminal of the ring-oscillation control circuit 110. When the evaluation enable signal EN indicates that the evaluation is started, the ring-oscillation control circuit 110 couples the input terminal of the ring-oscillation control circuit 110 to the output terminal of the ring-oscillation control circuit. At this time, the internal control signal WLE1_N of the SRAM instance 120_N is provided to the SRAM instance 120_1 as the WLE signal WLE1_0. When the WLE signal WLE1_0 is a logic low level, the internal control signal WLE1_1 of the SRAM instance 120_1 is a logic high level. When the internal control signal WLE1_1 of the SRAM instance 120_1 is a logic high level, the internal control signal WLE1_1 of the SRAM instance 120_2 is a logic low level. By analogy, the internal control signal WLE1_N of the SRAM instance 120_N will transition the WLE signal WLE1_0 from a logic low level to a logic high level. Therefore, the SRAM ring oscillator shown in FIG. 1 can perform oscillation operations.

To sum up, the evaluation circuit 100 uses the plurality of SRAM instances 120_1 to 120_N to form the SRAM ring oscillator. Any SRAM instance (complete SRAM integrated circuit) in the SRAM ring oscillator generates different internal control signals (used to control different functional circuits local to the SRAM instances) based on the WLE signal received by its own WLE signal input terminal. At least one of the internal control signals is transmitted to the internal signal output terminal as a WLE signal for another SRAM instance. On advanced processes (such as 22 nm, 14 nm, 7 nm . . . and other processes), process variations are difficult to predict. By comparing the actual oscillation signal of the SRAM ring oscillator (the internal control signal output by any one-stage SRAM instance) to the simulation waveform, the analysis platform (not shown) can extract instance level AC information, instance level DC information, and other information, and also track the process information of memory cell current, the process information of memory metal RC loading model, and the process information of memory internal signal. Therefore, the evaluation circuit 100 can be used to track memory silicon to simulation (S2S) performance. The evaluation circuit 100 may be placed on a wafer process monitoring structure for product SRAM instance monitoring. The evaluation circuit 100 can be widely used to calibrate process variations.

Each SRAM instance shown in FIG. 1 is a complete SRAM integrated circuit product. The embodiment does not limit the specific implementation of the SRAM instances 120_1 to 120_N. For example, the following embodiment will illustrate one of many implementation examples for any one of the SRAM instances 120_1 to 120_N.

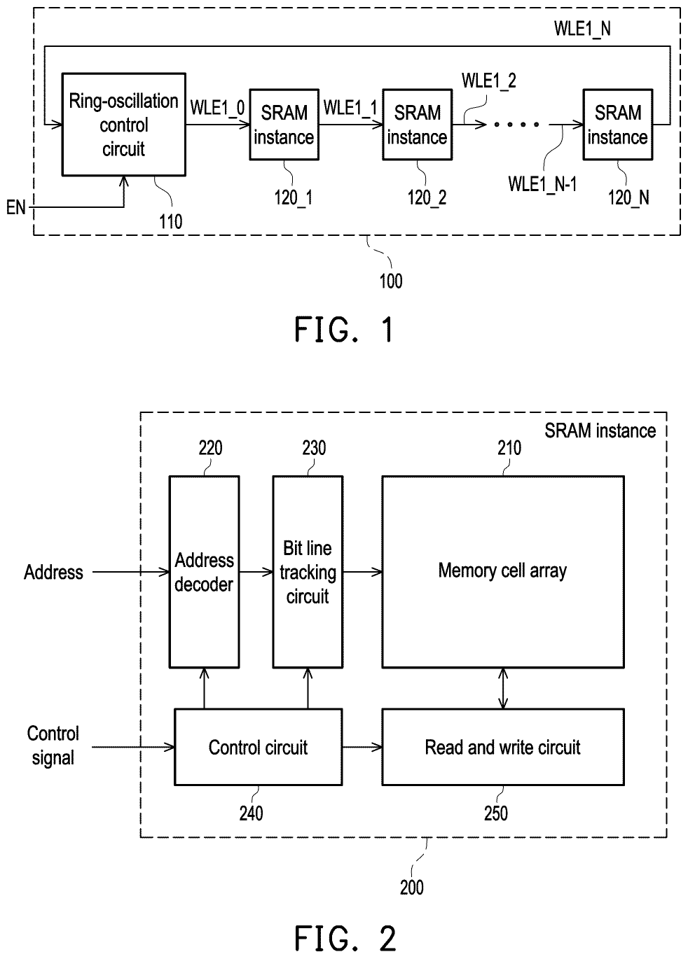

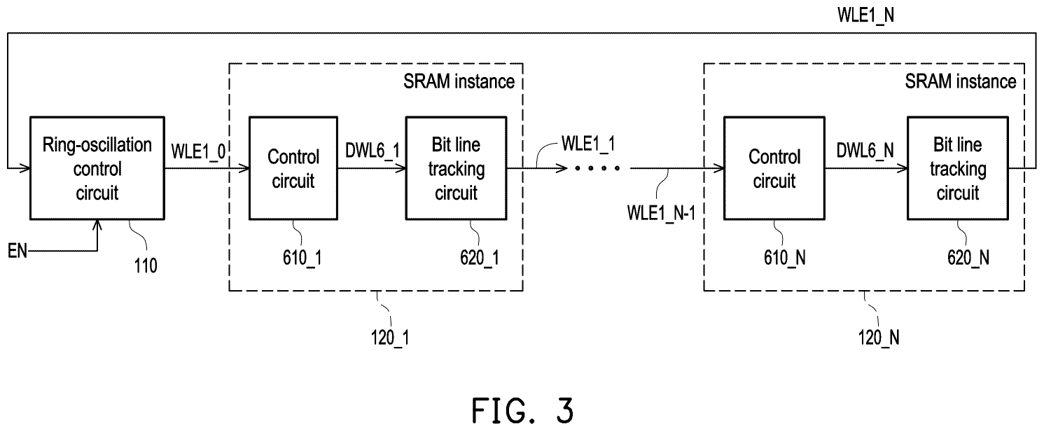

FIG. 2 is a schematic circuit block diagram of an SRAM instance 200 according to an embodiment of the disclosure. The SRAM instance 200 shown in FIG. 2 can be used as one of many implementation examples of any one of the SRAM instances 120_1 to 120_N shown in FIG. 1. The SRAM instance 200 shown in FIG. 2 includes a memory cell array 210 and its peripheral circuits. The memory cell array 210 includes a plurality of memory cells (not shown), a plurality of word lines (WLs, not shown), and a plurality of bit lines (BLs, not shown). The peripheral circuits may perform read operations, write operations, and other functional operations on the memory cell array 210. In the embodiment shown in FIG. 2, the peripheral circuits include an address decoder 220, a bit line tracking (BL tracking) circuit 230, a control circuit 240, and a read and write circuit 250. Based on control signals provided by an external circuit (not shown, such as a memory controller), for example, WL enable (WLE) signal and other control signals, the control circuit 240 generates different internal control signals to control different functional circuits, such as the address decoder 220, the BL tracking circuit 230, and the read and write circuit 250. For example, the internal control signal includes the dummy word line (WL) signal, the BL precharge signal, the SAEN signal, the WL signal, the multiplexer select signal, or other internal control signals of the SRAM instance 200.

Based on the control of the control circuit 240, the address decoder 220 can decode the access address provided by an external circuit (not shown, such as a memory controller), and then drive at least one corresponding word line of the memory cell array 210 according to the decoding result. Based on the actual design, the address decoder 220 may include a conventional address decoder or other address decoder circuits. The BL tracking circuit 230 is coupled to the address decoder 220. The BL tracking circuit 230 drives the dummy bit line based on the decoding result to track at least one corresponding bit line of the memory cell array 210. Based on the actual design, the BL tracking circuit 230 may include a conventional BL tracking circuit or other BL tracking circuits. The read and write circuit 250 is coupled to the control circuit 240. Based on the control of the control circuit 240, the read and write circuit 250 performs read operations or write operations on the plurality of bit lines of the memory cell array 210. Based on the actual design, the read and write circuit 250 may include a conventional read and write circuit or other read and write circuits.

In the context of SRAM operational evaluation, in addition to the control circuit 240 receiving the WLE signal from an external circuit (not shown in FIG. 2, such as another SRAM instance or the ring-oscillation control circuit 110 shown in FIG. 1), other external control signals and addresses may not be provided to the SRAM instance 200. The control circuit 240 generates the dummy WL signal, the BL precharge signal, the SAEN signal, the WL signal, the multiplexer select signal, and other internal control signals based on the WLE signal at the WLE signal input terminal of the SRAM instance 200 to control the address decoder 220, the BL tracking circuit 230, and the read and write circuit 250.

The BL tracking circuit 230 drives the dummy bit line based on the dummy WL signal to generate the dummy bit line signal to the control circuit 240 or the read and write circuit 250. The BL tracking circuit 230 is used to track the current of the SRAM cell. When a certain target word line is turned on, the dummy WL is also turned on. Based on the voltage (or voltage drop, or current, or other electrical characteristics) of the turned-on dummy WL, the read and write circuit 250 performs read operations or write operations on a plurality of bit lines of the target word line. In some embodiments, the dummy bit line signal generated by the BL tracking circuit 230 can be used as an internal control signal output by the internal signal output terminal of the SRAM instance 200. In other embodiments, the BL precharge signal, the SAEN signal, the WL signal, the multiplexer select signal, or other memory internal signals generated by the control circuit 240 can be used as an internal control signal output by the internal signal output terminal of the SRAM instance 200.

FIG. 3 is a schematic circuit block diagram of the SRAM instances 120_1 to 120_N according to an embodiment of the disclosure. The SRAM instances 120_1 to 120_N shown in FIG. 3 can be used as one of many implementation examples of the SRAM instances 120_1 to 120_N shown in FIG. 1. The SRAM instance 120_1 shown in FIG. 3 includes a control circuit 610_1 and a BL tracking circuit 620_1. The control circuit 610_1 and the BL tracking circuit 620_1 shown in FIG. 3 may be deduced with reference to the related description of the control circuit 240 and the BL tracking circuit 230 shown in FIG. 2, and therefore it is not repeated herein. By the same token, the SRAM instance 120_N shown in FIG. 3 includes a control circuit 610_N and a BL tracking circuit 620_N.

Referring to FIG. 1 and FIG. 3, based on the WLE signal WLE1_0 provided by the ring-oscillation control circuit 110, the control circuit 610_1 generates a dummy WL signal DWL6_1 to control the BL tracking circuit 620_1. The BL tracking circuit 620_1 drives the dummy bit line based on the dummy WL signal DWL6_1 to generate the dummy bit line signal as the internal control signal WLE1_1 of the SRAM instance 120_1 to the SRAM instance 120_2. By analogy, based on the internal control signal WLE1_N−1 provided by the SRAM instance 120_N−1 (not shown), the control circuit 610_N generates a dummy WL signal DWL6_N to control a BL tracking circuit 620_N. The BL tracking circuit 620_N drives the dummy bit line based on the dummy WL signal DWL6_N to generate the dummy bit line signal as the internal control signal WLE1_N of the SRAM instance 120_N to the ring-oscillation control circuit 110.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. An evaluation circuit for SRAM operations, comprising:
a plurality of SRAM instances, connected in series with each other to form an SRAM string, wherein a WLE signal input terminal of an intermediate SRAM instance in the SRAM string is coupled to an internal signal output terminal of a previous-stage SRAM instance of the intermediate SRAM instance, and an internal signal output terminal of the intermediate SRAM instance is coupled to a WLE signal input terminal of a next-stage SRAM instance of the intermediate SRAM instance; and
a ring-oscillation control circuit, coupled to the SRAM string to form a ring oscillator circuit, wherein an input terminal of the ring-oscillation control circuit is coupled to an internal signal output terminal of a last-stage SRAM instance in the SRAM string, and an output terminal of the ring-oscillation control circuit is coupled to a WLE signal input terminal of a first-stage SRAM instance in the SRAM string.

2. The evaluation circuit according to claim 1, wherein the ring-oscillation control circuit is controlled by an evaluation enable signal, when the evaluation enable signal indicates that an evaluation is started, the ring-oscillation control circuit couples the input terminal of the ring-oscillation control circuit to the output terminal of the ring-oscillation control circuit, and when the evaluation enable signal indicates that the evaluation is terminated, the ring-oscillation control circuit disconnects a connection between the input terminal of the ring-oscillation control circuit and the output terminal of the ring-oscillation control circuit.

3. The evaluation circuit according to claim 1, wherein the internal signal output terminal of any one of the SRAM instances is configured to output an internal control signal.

4. The evaluation circuit according to claim 3, wherein the internal control signal comprises a dummy bit line signal, a BL precharge signal, a SAEN signal, a WL signal, or a multiplexer select signal.

5. The evaluation circuit according to claim 1, wherein any one of the SRAM instances comprises:
a memory cell array;
an address decoder, configured to decode an access address, and drive at least one corresponding word line of the memory cell array according to a decoding result; and
a BL tracking circuit, coupled to the address decoder, wherein the BL tracking circuit drives a dummy bit line based on the decoding result to track at least one corresponding bit line of the memory cell array.

6. The evaluation circuit according to claim 5, wherein any one of the SRAM instances further comprises:
a control circuit, configured to control the address decoder and the BL tracking circuit; and
a read and write circuit, coupled to the control circuit, wherein the read and write circuit performs read operations or write operations on a plurality of bit lines of the memory cell array based on a control of the control circuit.

7. The evaluation circuit according to claim 6, wherein the control circuit generates a dummy WL signal, a BL precharge signal, a SAEN signal, a WL signal, and a multiplexer select signal based on a WLE signal at the WLE signal input terminal to control the address decoder, the BL tracking circuit, and the read and write circuit.

8. The evaluation circuit according to claim 7, wherein the BL tracking circuit drives the dummy bit line based on the dummy WL signal to generate a dummy bit line signal as an internal control signal output by the internal signal output terminal.

9. The evaluation circuit according to claim 7, wherein the BL precharge signal, the SAEN signal, the WL signal, or the multiplexer select signal generated by the control circuit are used as an internal control signal output by the internal signal output terminal.
